(19) United States
(12) Patent Application Publication
(10) Pub. No.: US 2025/0267894 A1
(43) Pub. Date: Aug. 21, 2025

(54) SEMICONDUCTOR DEVICE AND METHOD OF MANUFACTURING THE SAME

(71) Applicant: Taiwan Semiconductor Manufacturing Company, Ltd., Hsinchu (TW)

(72) Inventors: Han YEH, Hsinchu (TW); Yu-Lien HUANG, Hsinchu (TW); Yuan-Sheng HUANG, Hsinchu (TW); Yung-Cheng LU, Hsinchu (TW)

(73) Assignee: Taiwan Semiconductor Manufacturing Company, Ltd., Hsinchu (TW)

(21) Appl. No.: 18/444,092

(22) Filed: Feb. 16, 2024

(51) Int. Cl. H01L 29/423; H01L 29/06; H01L 29/66; H01L 29/775; H01L 29/786

(52) U.S. Cl. CPC H10D 30/6735; H10D 30/014; H10D 30/43; H10D 30/6757; H10D 62/113; H10D 62/121; H10D 64/017

(57) ABSTRACT

A method of manufacturing a semiconductor device is provided with following steps. A fin structure is formed over a substrate. A sacrificial gate structure is formed over the fin structure. A source/drain region of the fin structure is etched, the source/drain region is not covered by the sacrificial gate structure, and thereby a source/drain space is formed. An isolation region at a bottom portion of the source/drain space is formed. A doped source/drain epitaxial layer is formed over the isolation region in the source/drain space. A conductive contact layer is formed over the doped source/drain epitaxial layer. At least one interlayer dielectric layer is formed and at least one conductive contact plug is formed to pass through the at least one interlayer dielectric layer to electrically connect to the conductive contact layer.

### BACKGROUND

As the semiconductor industry introduces new generations of integrated circuits (IC) having higher performance and more functionality, the density of the elements forming the ICs increases, while the dimensions, sizes and spacing between components or elements are reduced. The semiconductor industry continues to improve the integration density of various electronic components (e.g., transistors, diodes, resistors, capacitors, etc.) by continual reductions in minimum feature size, which allow more components to be integrated into a given area.

However, the traditional interlayer oxide layer (ILD-OX) is made of silicon oxide so that the effective capacitance between the conductive metal layer and the metal gate increases due to the high dielectric constant of silicon oxide.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a schematic cross-sectional view of a semiconductor gate-all-around (GAA) field effect transistor device according to an embodiment of the present disclosure.

FIGS. 2A to 2C respectively illustrate a schematic diagram of a process of manufacturing a semiconductor device according to an embodiment of the present disclosure.

FIG. 3 shows a schematic cross-sectional view of a fin field effect transistor device according to an embodiment of the present disclosure.

FIG. 4 is a schematic diagram of a method of manufacturing a semiconductor device according to an embodiment of the present disclosure.

FIG. 5 shows a schematic cross-sectional view of a fin field effect transistor device according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

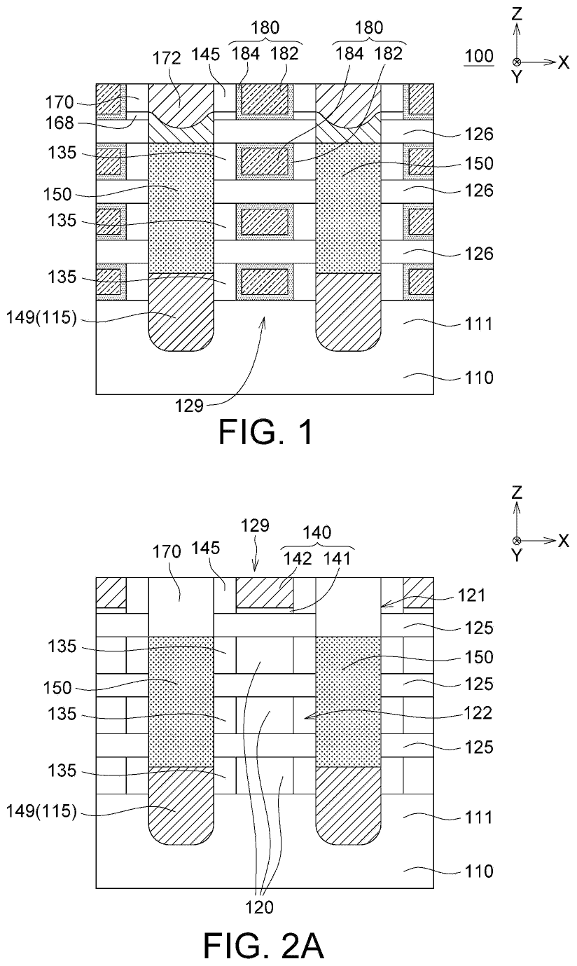

FIG. 1 is a cross sectional view of a semiconductor device 100 along X direction (source-drain direction). As shown in FIG. 1, channel regions 126 are provided over a semiconductor substrate 110, and vertically arranged along the Z direction (the normal direction to the principal surface of the substrate 110). In some embodiments, the substrate 110 includes a single crystalline semiconductor layer on at least its surface portion. The substrate 110 may comprise a single crystalline semiconductor material such as, but not limited to Si, Ge, SiGe, GaAs, InSb, GaP, GaSb, InAlAs, InGaAs, GaSbP, GaAsSb and InP. In certain embodiments, the substrate 110 is made of crystalline Si.

The substrate 110 may include in its surface region, one or more buffer layers (not shown). The buffer layers can serve to gradually change the lattice constant from that of the substrate to that of the source/drain region. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In a particular embodiment, the substrate 110 comprises silicon germanium (SiGe) buffer layers epitaxially grown on the silicon substrate 110. The germanium concentration of the SiGe buffer layers may increase from 30 atomic % germanium for the bottom-most buffer layer to 70 atomic % germanium for the top-most buffer layer.

As shown in FIG. 1, the semiconductor wires or sheets (collectively nano-structures), which constitute channel regions 126, are disposed over the substrate 110. In some embodiments, the channel regions 126 are disposed over a base portion 111 of a fin structure (see, FIG. 1) protruding from the substrate 110. Each of the channel regions 126 is wrapped around by a gate dielectric layer 182 and a gate electrode layer 184. The thickness of the channel regions 126 is in a range from about 5 nm to about 60 nm and the width of the channel regions 126 is in a range from about 5 nm to about 120 nm in some embodiments. In some embodiments, the width of the channel regions 126 is greater than 120 nm. In certain embodiments, the width is up to twice or five times the thickness of the channel regions 126. In some embodiments, the channel regions 126 are made of Si, SiGe or Ge.

In some embodiments, the gate dielectric layer 182 includes a high-k dielectric layer. The gate structure 180 includes the gate dielectric layer 182, the gate electrode layer 184 and sidewall spacers 145. Although FIG. 1 shows three channel regions 126, the number of the channel regions 126 is not limited to three, and may be as small as one and two or more than three, and may be up to 15. By adjusting the number of the semiconductor wires or sheets, a driving current of the GAA FET device can be adjusted.

Further, a source/drain epitaxial layer 150 is disposed in or on the substrate 110. The source/drain epitaxial layer 150 is in direct contact with end faces of the channel regions 126, and is separated by insulating inner spacers 135 and the gate dielectric layer 182 from the gate electrode layer 184. In some embodiments, a base epitaxial layer 149 or an isolation region 115 is formed below the source/drain epitaxial layer 150, the isolation region 115 prevents current leakage between the source/drain epitaxial layer 150 and the base portion 111 of the fin structures 129 and between the source/drain epitaxial layer 150 and the substrate 110. In some embodiments, the isolation region 150 provides a current barrier or a voltage barrier.

In some embodiments, the channel region 126 and the base epitaxial layer 149 are made of the same material (e.g., Si, SiGe or Ge), except for a dopant condition (doping type/element and/or doping concentration). In some embodiments, the base epitaxial layer 149 is made of non-doped semiconductor material and the channel region 126 are made of the non-doped or doped semiconductor material. In some embodiments, when the base epitaxial layer 149 and the channel region 126 (wires or sheets) are made of SiGe, the Ge amount of the base epitaxial layer 149 and the channel region 126 is the same or different from each other. In other embodiments, the channel region 126 and the base epitaxial layer 149 are made of different semiconductor material.

In some embodiments, an additional insulating layer (not shown) is conformally formed on a surface of the insulating inner spacers 135 between the insulating inner spacers 135 and the gate electrode layer 184. As shown FIG. 1, the cross section, perpendicular to the Y direction, of the insulating inner spacer 135 has a rounded convex shape (e.g., semi-circular or U-shape) toward the gate electrode layer 184.

An interlayer dielectric (ILD) layer 170 is disposed over the source/drain epitaxial layer 150 and a conductive contact layer 172 is disposed on the source/drain epitaxial layer 150, and a conductive contact plug 175 passing though the ILD layer 170 is disposed over the conductive contact layer 172. The conductive contact layer 172 includes one or more layers of conductive material. In some embodiments, the conductive contact layer 172 includes a silicide layer, such as WSi, NiSi, TiSi or CoSi or other suitable silicide material or an alloy of a metal element and silicon and/or germanium. In some embodiments, an etch stop layer 168 is disposed between the sidewall spacers 145 and the ILD layer 170 and on a part of the upper surface of the source/drain epitaxial layer 150.

In some embodiments, the FET shown in FIG. 1 is a p-type FET. The source/drain epitaxial layer includes one or more layers of Si, SiGe, Ge, SiGeSn, SiSn and GeSnP. In some embodiments, the source/drain epitaxial layer further includes boron (B). In some embodiments, the FET shown in FIG. 1 is an n-type FET and the epitaxial layer includes one or more layers of Si, SiC, SiGe, Ge, SiGeSn, SiSn and GeSnP. In some embodiments, the source/drain epitaxial layer further includes phosphor (P).

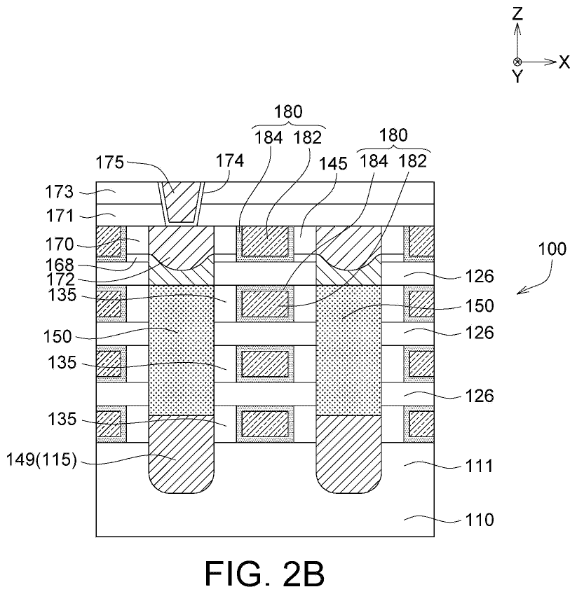

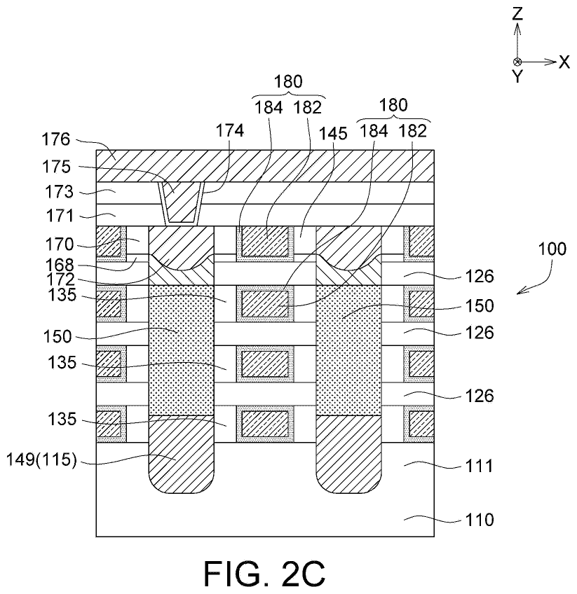

The manufacturing process of semiconductor FET device as shown in FIGS. 2A, 2B and 2C are provided as follows. First, referring to FIGS. 2A, first semiconductor layers 120 and second semiconductor layers 125 are alternately formed over the substrate 110. The first semiconductor layers 120 and the second semiconductor layers 125 are made of materials having different lattice constants, and may include one or more layers of Si, Ge, SiGe, GaAs, InSb, GaP, GaSb, InAlAs, InGaAs, GaSbP, GaAsSb or InP. The second semiconductor layers 125 are consistent with the channel regions 126 of FIG. 1.

The first semiconductor layers 120 and the second semiconductor layers 125 are epitaxially formed over the substrate 110. The thickness of the first semiconductor layers 120 may be equal to or greater than that of the second semiconductor layers 125, and is in a range from about 5 nm to about 60 nm in some embodiments, and is in a range from about 10 nm to about 30 nm in other embodiments. The thickness of the second semiconductor layers 125 is in a range from about 5 nm to about 60 nm in some embodiments, and is in a range from about 10 nm to about 30 nm in other embodiments. The thickness of the first semiconductor layers 120 may be the same as, or different from the thickness of the second semiconductor layers 125. Although three first semiconductor layers 120 and four second semiconductor layers 125 are provided, the numbers are not limited to three, and can be 1, 2, or more than 3, and is less than 20.

After the stacked semiconductor layers are formed, fin structures are formed by using one or more lithography and etching operations, as shown in FIG. 2A. The fin structures 129 may be patterned by any suitable method. For example, the fin structures 129 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

As shown in FIG. 2A, the fin structures 129 extend in the X direction and are arranged in the Y direction. The number of the fin structures is not limited to two or three, and may be as small as one or more. In some embodiments, one or more dummy fin structures are formed on both sides of the fin structures 129 to improve pattern fidelity in the patterning operations. As shown in FIG. 2A, the fin structures 129 have upper portions constituted by the stacked first and second semiconductor layers 120, 125 and over the base portion 111 of the substrate 110.

After the fin structures 129 are formed, an insulating material layer (not shown) including one or more layers of insulating material is formed over the substrate 110 so that the fin structures 129 are fully embedded in the insulating layer. The insulating material for the insulating layer may include silicon oxide, silicon nitride, silicon oxynitride (SiON), SiOCN, SiCN, fluorine-doped silicate glass (FSG), or a low-k dielectric material, formed by LPCVD (low pressure chemical vapor deposition), plasma-enhanced CVD (PECVD) or flowable CVD. An anneal operation may be performed after the formation of the insulating layer. Then, a planarization operation, such as a chemical mechanical polishing (CMP) method and/or an etch-back method, is performed such that the upper surface of the uppermost second semiconductor layer 125 is exposed from the insulating material layer. In some embodiments, one or more fin liner layers are formed over the fin structures before forming the insulating material layer. In some embodiments, the fin liner layers include a first fin liner layer formed over the substrate 110 and sidewalls of the base portion 111 of the fin structures 129, and a second fin liner layer formed on the first fin liner layer. The fin liner layers are made of silicon nitride or a silicon nitride-based material (e.g., SiON, SiCN or SiOCN). The fin liner layers may be deposited through one or more processes such as physical vapor deposition (PVD), chemical vapor deposition (CVD), or atomic layer deposition (ALD), although any acceptable process may be utilized.

Then, as shown in FIG. 2A, the insulating material layer is recessed to form an isolation insulating layer 115 so that the upper portions of the fin structures 129 are exposed. With this operation, the fin structures 129 are separated from each other by the isolation insulating layer, which is also called a shallow trench isolation (STI). The isolation insulating layer may be made of suitable dielectric materials such as silicon oxide, silicon nitride, silicon oxynitride, fluorine-doped silicate glass (FSG), low-k dielectrics such as carbon doped oxides, extremely low-k dielectrics such as porous carbon doped silicon dioxide, a polymer such as polyimide, combinations of these, or the like. In some embodiments, the isolation insulating layer is formed through a process such as CVD, flowable CVD (FCVD), or a spin-on-glass process, although any acceptable process may be utilized.

In some embodiments, the isolation insulating layer is recessed until the upper portion of the fin structure 129 over the base portion 111 is exposed. In other embodiments, the upper portion of the fin structure 129 is not exposed. The first semiconductor layers 120 are sacrificial layers which are subsequently partially removed, and the second semiconductor layers 125 are subsequently formed into semiconductor wires as channel regions 126 of the GAA FET. In other embodiments, the second semiconductor layers 125 are sacrificial layers which are subsequently partially removed, and the first semiconductor layers 120 are subsequently formed into semiconductor wires as channel regions 126.

After the isolation insulating layer is formed, a sacrificial (dummy) gate structure is formed. The sacrificial gate structure 140 is formed over a portion of the fin structure 129 which is to be a channel region. The sacrificial gate structure 140 defines the channel region of the GAA FET. The sacrificial gate structure 140 includes a sacrificial gate dielectric layer 141 and a sacrificial gate electrode layer 142. The sacrificial gate dielectric layer 141 includes one or more layers of insulating material, such as a silicon oxide-based material. In one embodiment, silicon oxide formed by CVD is used. The thickness of the sacrificial gate dielectric layer 141 is in a range from about 1 nm to about 5 nm in some embodiments.

The sacrificial gate structure 140 is formed by first blanket depositing the sacrificial gate dielectric layer 141 over the fin structures 129. A sacrificial gate electrode layer 142 is then blanket deposited on the sacrificial gate dielectric layer 141 and over the fin structures, such that the fin structures are fully embedded in the sacrificial gate electrode layer 142. The sacrificial gate electrode layer 142 includes silicon such as polycrystalline silicon or amorphous silicon. The thickness of the sacrificial gate electrode layer 142 is in a range from about 100 nm to about 200 nm in some embodiments. In some embodiments, the sacrificial gate electrode layer 142 is subjected to a planarization operation. The sacrificial gate dielectric layer 141 and the sacrificial gate electrode layer 142 are deposited using CVD, including LPCVD and PECVD, PVD, ALD, or other suitable process. Subsequently, a mask layer is formed over the sacrificial gate electrode layer. The mask layer includes a pad silicon nitride layer and a silicon oxide mask layer.

In some embodiments, the recessed source/drain space 121 is formed by a dry etching process, which may be anisotropic. The anisotropic etching process may be performed using a process gas mixture including BF₂, Cl₂, CH₃F, CH₄, HBr, O₂, Ar, other etchant gases. The plasma is a remote plasma that is generated in a separate plasma generation chamber connected to the processing chamber. Process gases may be activated into plasma by any suitable method of generating the plasma, such as transformer coupled plasma (TCP) systems, inductively coupled plasma (ICP) systems, magnetically enhanced reactive ion techniques. The process gases used in the plasma etching process includes etchant gases such as H₂, Ar, other gases, or a combination of gases. In some embodiments, carrier gases, such as N₂, Ar, He, Xe, plasma etching process using hydrogen (H) radicals.

In addition, the first semiconductor layers 120 are laterally etched in the X direction within the source/drain space 121, thereby forming cavities 122. When the first semiconductor layers 120 are SiGe and the second semiconductor layers 125 are Si, the first semiconductor layers 120 can be selectively etched by using a wet etchant such as, but not limited to, a mixed solution of H₂O₂, CH₃COOH and HF, followed by H₂O cleaning. In some embodiments, the etching by the mixed solution and cleaning by water is repeated 10 to 20 times. The etching time by the mixed solution is in a range from about 1 min to about 2 min in some embodiments. The mixed solution is used at a temperature in a range from about 60° C. to about 90° C. in some embodiments. In some embodiments, other etchants are used.

The first insulating layer is formed on the etched lateral ends of the first semiconductor layers 120, e.g., the cavities 122, and on end faces of the second semiconductor layers 125 in the source/drain space 121 and is formed over the sacrificial gate structure 140 of the two semiconductor GAA FET devices. The first insulating layer includes one of silicon nitride and silicon oxide, SiON, SiOC, SiCN and SiOCN, or any other suitable dielectric material. The first insulating layer 30 is made of a different material than the sidewall spacers 145 (first cover layer). The first insulating layer has a thickness in a range from about 1.0 nm to about 10.0 nm in some embodiments. In other embodiments, the first insulating layer has a thickness in a range from about 2.0 nm to about 5.0 nm. The first insulating layer can be formed by ALD or any other suitable methods. By conformally forming the first insulating layer, the cavities 122 of the first semiconductor layers 120 in the source/drain space 121 are fully filled with the first insulating layer.

The doped epitaxial layers 150 are grown in the source/drain space 121 of the semiconductor device. Next, the ILD layer 170 (not shown) is formed over the source/drain epitaxial layer 150, the sacrificial gate structure 140, and the sidewall spacers 145. After the ILD layer 170 is formed over the semiconductor device, a planarization operation, such as CMP, is performed, so that the top portion of the sacrificial gate electrode layer 142 is exposed. Then the sacrificial gate electrode layer 142 and sacrificial gate dielectric layer 141 are removed. The ILD layer 170 protects the doped source/drain epitaxial layer 150 during the removal of the sacrificial gate structures 40. The sacrificial gate structures 40 can be removed using plasma dry etching and/or wet etching. When the sacrificial gate electrode layer 142 is polysilicon and the ILD layer 170 is silicon oxide, a wet etchant such as a TMAH solution can be used to selectively remove the sacrificial gate electrode layer 142. The sacrificial gate dielectric layer 141 is thereafter removed using plasma dry etching and/or wet etching.

After the sacrificial gate structures 140 are removed, the first semiconductor layers 120 are removed, thereby forming wires or sheets (channel regions) of the second semiconductor layers 125. The first semiconductor layers 120 can be removed/etched using an etchant that can selectively etch the first semiconductor layers 120 against the second semiconductor layers 125 and against the inner spacers 135 that act as etch stops. In some embodiments, the etched sacrificial gate dielectric layer 141 and the etched sacrificial gate electrode layer 142 are replaced with a metal gate structure 180 that includes the gate dielectric layer 182 and the gate electrode layer 184 are respectively disposed. In addition, the gate electrode layer 184 is disposed in the location of the first semiconductor layers 120 that is sandwiched between two layer of the gate dielectric layer 182 (shown in FIG. 1).

In FIG. 2B, after the metal gate structure 180 is formed, the ILD layer 170 is patterned and a conductive contact layer 172 is formed over the doped epitaxial layers 820 and a conductive contact plug 175 is formed on the conductive contact layer 172. In some embodiments, the conductive contact layer 172 includes one or more of Co, Ni, W, Ti, Ta, Cu, Al, silicide thereof, TiN and TaN. The conductive contact plug 75 includes one or more layers of Co, Ni, W, Ti, Ta, Cu, Al, TiN and TaN.

As shown in FIG. 2B, the ILD layers 170 and 173 may be formed over one or more semiconductor devices 100, such as transistors, diodes, image sensors, resistors, capacitors, inductors, memory cells, the above combinations, and/or other suitable devices. In some embodiments, the semiconductor devices 100 is such as a nanostructure field effect transistor having a plurality of channels surrounded by a gate electrode layer as shown in FIG. 1.

The etch stop layers (ESL) 171 may be formed under the ILD layer 173. An etch stop layer (ESL) 171 may be used to control the etch depth of the ILD layer 173 when forming conductive contact plug 175 within the ILD layer 173. In some embodiments, the etch stop layer (ESL) 171 may include SiNx, SiCxNy, SiOxCy, SiCx, or other suitable materials. In some embodiments, the etch stop layer (ESL) 171 can be deposited at a temperature between 450 degrees Celsius and 300 degrees Celsius by chemical vapor deposition (CVD), physical vapor deposition (PVD), atomic layer deposition (ALD), spin coating or other suitable process.

In some embodiments, the ILD layer 173 can be made of amorphous SiOx, SiOxCyHz, SiOxCy, SiCx or related low-k materials, and the range of k value can be between 2.0 and 3.0 or between 2.5 and 3.5. The ILD layer 173 may be made of SiOx, SiOxCyHz, SiOxCy, SiCx or related low-k materials with ordered pores or non-porosity. As used herein, the term “ordered pores” refers to voids or air gaps formed in a dielectric material in a predetermined arrangement and filled with air. The ILD layer 173 with ordered pores has the characteristics of low dielectric constant and high mechanical strength. In some embodiments, the ILD layer 173 can be deposited at a temperature between 450 degrees Celsius and 300 degrees Celsius by chemical vapor deposition (CVD), physical vapor deposition (PVD), atomic layer deposition (ALD), spin coating or other suitable process. In some embodiments, additional annealing or ultraviolet (UV) curing processes may be performed in the fabrication of the ILD layer 173 or may not be used.

In some embodiments, the conductive contact plug 175 may include Cu, Ni, Co, Ru, Ir, Al, Pt, Pd, Au, Ag, Os, W, Mo, and related alloys. The conductive contact plug 175 can be formed by atomic layer deposition (ALD), chemical vapor deposition (CVD), physical vapor deposition (PVD), electroless deposition (ELD), electrochemical plating (ECP) at a temperature between 450 degrees Celsius and 300 degrees Celsius or other suitable process.

In some embodiments, a barrier layer 174 can be formed between the dielectric layer 173 and the conductive contact plug 175. In some embodiments, the conductive contact plug 175 can be formed in the dielectric layer 173 by dual damascene, single damascene, half damascene or other suitable process. Taking the single damascene process as an example, the etch stop layer (ESL) 171 and the ILD layer 173 are sequentially deposited, and the ILD layer 173 is etched to form openings according to a predefined pattern. Then, the barrier layer 174 is deposited in the opening, and a conductive material (e.g., copper) is deposited on the barrier layer 174. The conductive material is deposited on the barrier layer 174 in the opening. A seed layer can be formed on the barrier layer 174 through a physical vapor deposition (PVD) process, and then a conductive material can be formed on the seed layer through an electrodeposition process. Afterwards, the top surface of the conductive material is planarized so that the top surfaces of the conductive contact plug 175, the barrier layer 174 and the ILD layer 173 are substantially coplanar.

In some embodiments, the ILD layer 173 may include a silicon-containing material (such as silicon carbonitride (SiCN), silicon oxycarbide (SiOC) or other suitable materials), and the ILD layer 173 may serve as a hermetic layer to prevent water and oxygen from penetrating. In some embodiments, the concentration of carbon, oxygen, and/or nitrogen in the ILD layer 173 may be largely related to the molecular weight of the precursor. Alternatively, another method to control the composition of the ILD layer 173 is to change the flow rate of the precursor and/or change the species of the reactive gas to control the composition of the silicon carbide film.

In some embodiments, the ILD layer 173 is a low dielectric constant silicon carbide film (such as SiOC). The dielectric constant of the ILD layer 173 can be adjusted by selecting an appropriate precursor to produce a specific C:O ratio. In some embodiments, the dielectric constant of the ILD layer 173 may be about 3.1 or less.

When the density of the ILD layer 173 increases, the hermeticity and diffusion barrier properties of the ILD layer 173 will be improved. Increases in density can be achieved by increasing the amount of crosslinks. The increase in cross-linking improves the hermeticity and diffusion barrier properties of the ILD layer 173 by introducing a small amount of oxygen into the silicon carbide film. Therefore, a precursor with a relatively high C:O ratio can enhance the hermeticity and diffusion barrier properties of the ILD layer 173.

Table 1 is a comparison of traditional interlayer oxide layer (ILD-OX) and low dielectric constant silicon carbide film (such as SiOC), including dielectric constant, breakdown voltage (VBD), density, leakage current, silicon percentage, oxygen percentage and carbon percentage. The range of carbon percentage of SiOC may be between about 20 and about 25.

TABLE 1

| | Traditional | Low k silicon |
|---|---|---|
| | interlayer oxide | carbide film of the |
| | layer (ILD-OX) | present disclosure |
| Dielectric constant (k) | 3.9 | 3.1 |
| Breakdown voltage | 12 | 5.9 |
| (MV/cm) | | |
| Density (g/cm³) | 2.1 | 1.57 |
| Leakage (nA)(at 2 MV/cm) | 7.6 | 3 |
| silicon percentage (%) | 67 | 30 |
| oxygen percentage (%) | 33 | 45-50 |
| carbon percentage (%) | 0 | 20-25 |

In addition, replacing the traditional interlayer oxide layer (ILD-OX) with a low dielectric constant silicon carbide film (such as SiOC) can reduce the capacitance value of the interconnection structure, so that the effective capacitance between the conductive metal layer and the metal gate can be reduced. Taking the interlayer oxide layer (ILD-OX) with a thickness of 12 nanometers and a k value of 3.9 as an example, changing the interlayer oxide layer to a silicon carbide film (such as SiOC) with a thickness of 12 nanometers and a k value of 3.1 can reduce the alternating current of ring oscillation (RO_AC) from about −1% to about −1.8%.

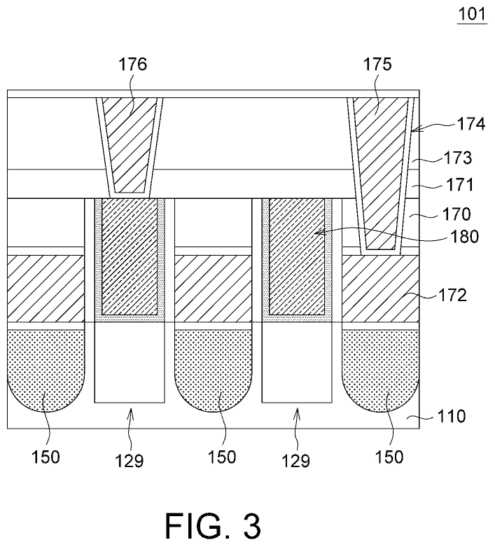

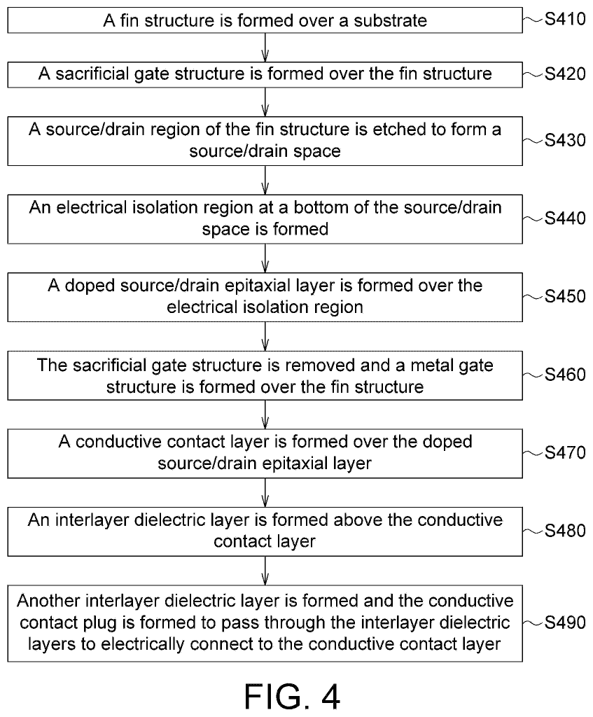

Referring to FIGS. 3 and 4, FIG. 3 is a schematic cross-sectional view of a fin field effect transistor device according to an embodiment of the present disclosure, and FIG. 4 shows a flow diagram of a method for manufacturing a semiconductor device as shown in FIG. 3 on a substrate in accordance with some embodiments of the present disclosure. In some embodiments, a fin structure 129 is formed over a substrate 110 in operation S410 and a sacrificial gate structure is formed over the fin structure 129 in operation S420. A source/drain region of the fin structure 129 is etched to form a source/drain space 121 in operation S430. An electrical isolation region 115 at a bottom of the source/drain space 121 is formed in operation S440 and a doped source/drain epitaxial layer 150 is formed over the electrical isolation region 115 in operation S450. Also, in operation S460, the sacrificial gate structure 140 is removed and a metal gate structure 180 is formed over the fin structure 129. In operation S470, a conductive contact layer 172 is formed over the doped source/drain epitaxial layer 150. In operation S480, an interlayer dielectric layer 170 is formed above the conductive contact layer 172, wherein the interlayer dielectric layer 170 surrounds the side walls of the metal gate structure 180. In operation S490, another interlayer dielectric layer 173 is formed over the interlayer dielectric layer 170 and the metal gate structure 180, and the conductive contact plug 175 is formed to pass through the interlayer dielectric layers 170, 173 to electrically connect to the conductive contact layer 172. In addition, another conductive contact plug 176 is formed to pass through the interlayer dielectric layers 173 to electrically connect to the metal gate structure 180. The interlayer dielectric layers 170 and 173 are, for example, low dielectric constant silicon carbide films (such as SiOC). Since SiOC has lower k value (e.g., equal to or less than 3.1) but keep comparable material properties with SiO₂, the semiconductor device 101 has benefits of smaller capacitance and smaller drain resistance (due to larger critical dimension of conductive contact layer).

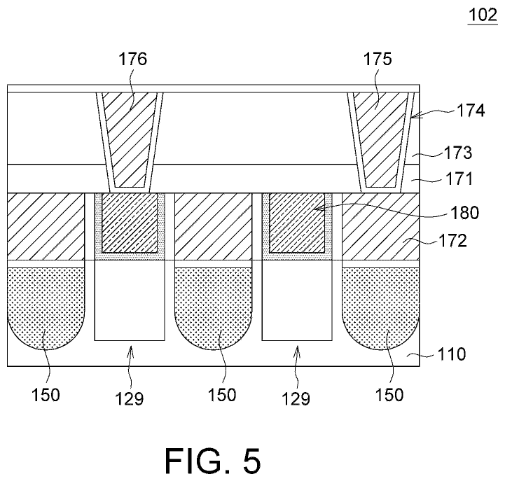

Referring to FIGS. 5 and 4, FIG. 5 is a schematic cross-sectional view of a fin field effect transistor device according to an embodiment of the present disclosure. The manufacturing process of the semiconductor device in FIG. 5 is similar to the manufacturing process of the semiconductor device in FIG. 3, as mentioned in the above operations. The difference is that after forming the conductive contact layer 172 above the doped epitaxial layer 150, a planarization process is performed, so that the top surface of the conductive contact layer 172 and the top surface of the metal gate structure 180 are coplanar. Next, an interlayer dielectric layer 173 is formed above the coplanar conductive contact layer 172 and the metal gate structure 180. The conductive contact plug 175 passes through the interlayer dielectric layer 173 and is electrically connected to the conductive contact layer 172. In addition, another conductive contact plug 176 passes through the interlayer dielectric layer 173 and is electrically connected to the metal gate structure. The interlayer dielectric layer 173 is, for example, a low dielectric constant silicon carbide film (such as SiOC). Since SiOC has lower k value (e.g., equal to or less than 3.1) but keep comparable material properties with SiO₂, the semiconductor device 102 has benefit of smaller capacitance and smaller drain resistance (due to larger critical dimension of conductive contact layer).

The present disclosure is related to a semiconductor device and a method of manufacturing the semiconductor device, in which at least one interlayer dielectric layer is formed and at least one conductive contact plug is formed to pass through the at least one interlayer dielectric layer to electrically connect to the conductive contact layer. The interlayer dielectric layer is, for example, a low dielectric constant silicon carbide film (such as SiOC). Since SiOC has lower k value (e.g., equal to or less than 3.1) but keep comparable material properties with SiO₂, the semiconductor device has benefits of smaller capacitance and smaller drain resistance (due to larger critical dimension of conductive contact layer).

According to some embodiments, a method of manufacturing a semiconductor device is provided with following steps. A fin structure is formed over a substrate. A sacrificial gate structure is formed over the fin structure. A source/drain region of the fin structure is etched, the source/drain region is not covered by the sacrificial gate structure, thereby a source/drain space is formed. An isolation region at a bottom portion of the source/drain space is formed. A doped source/drain epitaxial layer is formed over the isolation region in the source/drain space. A conductive contact layer is formed over the doped source/drain epitaxial layer. At least one interlayer dielectric layer is formed and at least one conductive contact plug is formed to pass through the at least one interlayer dielectric layer to electrically connect to the conductive contact layer.

According to some embodiments, a method of manufacturing a semiconductor device is provided with following steps. A fin structure in which first semiconductor layers and second semiconductor layers are alternately stacked is formed. A sacrificial gate structure is formed over the fin structure. A source/drain region of the fin structure is etched, the source/drain region is not covered by the sacrificial gate structure, and thereby a source/drain space is formed. Cavities on an end of each of the first semiconductor layers where the first semiconductor layers intersect with the source/drain space are formed by laterally etching the first semiconductor layers through the source/drain space. An inner spacer made of a dielectric material is formed in the cavities of the first semiconductor layers. An electrical isolation region is formed at a bottom of the source/drain region. A doped source/drain epitaxial layer is formed over the electrical isolation region in the source/drain space. A conductive contact layer is formed over the doped source/drain epitaxial layer. At least one interlayer dielectric layer is formed and at least one conductive contact plug is formed to pass through the at least one interlayer dielectric layer to electrically connect to the conductive contact layer.

According to some embodiments, a semiconductor device includes semiconductor nanostructures, an electrical isolation region, a doped source/drain epitaxial layer, a gate dielectric layer, a gate electrode layer, a conductive contact layer, at least one interlayer dielectric layer, and at least one conductive contact plug. The semiconductor nanostructures are disposed over a substrate. The electrical isolation region is disposed over the substrate in a drain/source region. The doped source/drain epitaxial layer is in contact with the semiconductor nanostructures and is disposed over the electrical isolation region in the drain/source region. The gate dielectric layer is disposed on and wrapped around each of channel regions of the semiconductor nanostructures. The gate electrode layer is disposed on the gate dielectric layer and wrapped around each of the channel regions of the semiconductor nanostructures. The conductive contact layer is disposed over the doped source/drain epitaxial layer. The at least one interlayer dielectric layer is disposed over the conductive contact layer. The at least one conductive contact plug passes through the at least one interlayer dielectric layer to electrically connect to the conductive contact layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a fin structure over a substrate;
forming a sacrificial gate structure over the fin structure;
etching a source/drain region of the fin structure, the source/drain region being not covered by the sacrificial gate structure, thereby forming a source/drain space;
forming an isolation region at a bottom portion of the source/drain space;
forming a doped source/drain epitaxial layer over the isolation region in the source/drain space;
forming a conductive contact layer over the doped source/drain epitaxial layer; and
forming at least one interlayer dielectric layer and forming at least one conductive contact plug passing through the at least one interlayer dielectric layer to electrically connect to the conductive contact layer.

2. The method of claim 1, further comprising:
removing the sacrificial gate structure; and
forming a metal gate structure over the fin structure, wherein the interlayer dielectric layer surrounds side walls of the metal gate structure.

3. The method of claim 2, wherein the interlayer dielectric layer is a low dielectric constant silicon carbide film.

4. The method of claim 3, wherein the interlayer dielectric layer is made of SiOC, and the dielectric constant of SiOC is equal to or less than 3.1.

5. The method of claim 2, further comprising forming:
forming another interlayer dielectric layer over the interlayer dielectric layer and the metal gate structure; and
forming another conductive contact plug passing through the another interlayer dielectric layer to electrically connect to the metal gate structure.

6. The method of claim 5, wherein the another interlayer dielectric layer is a low dielectric constant silicon carbide film.

7. The method of claim 6, wherein the another interlayer dielectric layer is made of SiOC, and the dielectric constant of SiOC is equal to or less than 3.1.

8. A method of manufacturing a semiconductor device, comprising:
forming a fin structure in which first semiconductor layers and second semiconductor layers are alternately stacked;
forming a sacrificial gate structure over the fin structure;
etching a source/drain region of the fin structure, the source/drain region being not covered by the sacrificial gate structure, thereby forming a source/drain space;
forming cavities on an end of each of the first semiconductor layers where the first semiconductor layers intersect with the source/drain space by laterally etching the first semiconductor layers through the source/drain space;
forming an inner spacer made of a dielectric material in the cavities of the first semiconductor layers;
forming an electrical isolation region at a bottom of the source/drain region; and
forming a doped source/drain epitaxial layer over the electrical isolation region in the source/drain space;
forming a conductive contact layer over the doped source/drain epitaxial layer; and
forming at least one interlayer dielectric layer and forming at least one conductive contact plug passing through the at least one interlayer dielectric layer to electrically connect to the conductive contact layer.

9. The method of claim 8, further comprising forming:
removing the sacrificial gate structure; and
forming a metal gate structure over the fin structure, wherein the interlayer dielectric layer surrounds side walls of the metal gate structure.

10. The method of claim 9, wherein the interlayer dielectric layer is a low dielectric constant silicon carbide film.

11. The method of claim 10, wherein the interlayer dielectric layer is made of SiOC, and the dielectric constant of SiOC is equal to or less than 3.1.

12. The method of claim 9, further comprising forming:
forming another interlayer dielectric layer over the interlayer dielectric layer and the metal gate structure; and
forming another conductive contact plug passing through the another interlayer dielectric layer to electrically connect to the metal gate structure.

13. The method of claim 12, wherein the another interlayer dielectric layer is a low dielectric constant silicon carbide film.

14. The method of claim 13, wherein the another interlayer dielectric layer is made of SiOC, and the dielectric constant of SiOC is equal to or less than 3.1.

15. A semiconductor device, comprising:
semiconductor nanostructures disposed over a substrate;
an electrical isolation region disposed over the substrate in a drain/source region;
a doped source/drain epitaxial layer in contact with the semiconductor nanostructures and disposed over the electrical isolation region in the drain/source region;
a gate dielectric layer disposed on and wrapped around each of channel regions of the semiconductor nanostructures;
a gate electrode layer disposed on the gate dielectric layer and wrapped around each of the channel regions of the semiconductor nanostructures;
a conductive contact layer disposed over the doped source/drain epitaxial layer;
at least one interlayer dielectric layer disposed over the conductive contact layer; and
at least one conductive contact plug passing through the at least one interlayer dielectric layer to electrically connect to the conductive contact layer.

16. The semiconductor device of claim 15, further comprising a metal gate structure disposed over the semiconductor nanostructures, wherein the interlayer dielectric layer surrounds side walls of the metal gate structure.

17. The semiconductor device of claim 16, wherein the interlayer dielectric layer is a low dielectric constant silicon carbide film.

18. The semiconductor device of claim 17, wherein the interlayer dielectric layer is made of SiOC, and the dielectric constant of SiOC is equal to or less than 3.1.

19. The semiconductor device of claim 16, further comprising:
another interlayer dielectric layer disposed over the interlayer dielectric layer and the metal gate structure; and
another conductive contact plug passing through the another interlayer dielectric layer to electrically connect to the metal gate structure.

20. The semiconductor device of claim 19, wherein the another interlayer dielectric layer is made of SiOC, and the dielectric constant of SiOC is equal to or less than 3.1.
